(19) United States
(12) Patent Application Publication
(10) Pub. No.: US 2023/0301079 A1
(43) Pub. Date: Sep. 21, 2023

(54) SEMICONDUCTOR DEVICE AND METHOD FOR MANUFACTURING THE SAME

(71) Applicant: Kioxia Corporation, Tokyo (JP)

(72) Inventors: Naomi Yanai, Kuwana Mie (JP); Hiroshi Fujita, Mie Mie (JP); Tatsuhiko Koide, Kuwana Mie (JP)

(73) Assignee: Kioxia Corporation, Tokyo (JP)

(21) Appl. No.: 17/899,876

(22) Filed: Aug. 31, 2022

(30) Foreign Application Priority Data
Mar. 15, 2022 (JP) 2022-040557

(51) Int. Cl. H01L 27/11556; H01L 27/11582

(52) U.S. Cl. CPC H01L 27/11556; H01L 27/11582

(57) ABSTRACT

A method for manufacturing a semiconductor device includes forming a hole through a first film; forming a semiconductor layer along a side surface of the hole; forming a second film overlaying a first region of the semiconductor layer; forming a third film along a side surface of a second region of the semiconductor layer that is above the first region; removing the second film to expose a side surface of the first region; forming a fourth film containing a plurality of first atoms and disposed along the side surface of the first region of the semiconductor layer; and diffusing the first atoms into the first region of the semiconductor layer.

### CROSS-REFERENCE TO RELATED APPLICATION(S)

This application is based upon and claims the benefit of priority from Japanese Patent Application No. 2022-040557, filed Mar. 15, 2022, the entire contents of which are incorporated herein by reference.

### FIELD

Embodiments described herein relate generally to a semiconductor device and a method for manufacturing the same.

### BACKGROUND

Three-dimensional memories may be formed with a high-concentration impurity layer having a sharp concentration gradient, in a channel semiconductor layer in the vicinity of the bottom of a memory hole. With this structure, gate induced drain leakage (GIDL) that causes deletion of storage data of the three-dimensional memory efficiently occurs. Unfortunately, such a high-concentration impurity layer is difficult to form in a memory hole having a high aspect ratio.

### DESCRIPTION OF THE DRAWINGS

FIG. 1 is a perspective view illustrating a structure of a semiconductor device of a first embodiment.

FIG. 2 is a sectional view illustrating a structure of the semiconductor device of the first embodiment.

FIGS. 3A and 3B are enlarged sectional views illustrating structures of the semiconductor device of the first embodiment.

FIG. 4 is a sectional view (1/18) illustrating a method for manufacturing the semiconductor device of the first embodiment.

FIG. 5 is a sectional view (2/18) illustrating the method for manufacturing the semiconductor device of the first embodiment.

FIG. 6 is a sectional view (3/18) illustrating the method for manufacturing the semiconductor device of the first embodiment.

FIG. 7 is a sectional view (4/18) illustrating the method for manufacturing the semiconductor device of the first embodiment.

FIG. 8 is a sectional view (5/18) illustrating the method for manufacturing the semiconductor device of the first embodiment.

FIG. 9 is a sectional view (6/18) illustrating the method for manufacturing the semiconductor device of the first embodiment.

FIG. 10 is a sectional view (7/18) illustrating the method for manufacturing the semiconductor device of the first embodiment.

FIG. 11 is a sectional view (8/18) illustrating the method for manufacturing the semiconductor device of the first embodiment.

FIG. 12 is a sectional view (9/18) illustrating the method for manufacturing the semiconductor device of the first embodiment.

FIG. 13 is a sectional view (10/18) illustrating the method for manufacturing the semiconductor device of the first embodiment.

FIG. 14 is a sectional view (11/18) illustrating the method for manufacturing the semiconductor device of the first embodiment.

FIG. 15 is a sectional view (12/18) illustrating the method for manufacturing the semiconductor device of the first embodiment.

FIG. 16 is a sectional view (13/18) illustrating the method for manufacturing the semiconductor device of the first embodiment.

FIG. 17 is a sectional view (14/18) illustrating the method for manufacturing the semiconductor device of the first embodiment.

FIG. 18 is a sectional view (15/18) illustrating the method for manufacturing the semiconductor device of the first embodiment.

FIG. 19 is a sectional view (16/18) illustrating the method for manufacturing the semiconductor device of the first embodiment.

FIG. 20 is a sectional view (17/18) illustrating the method for manufacturing the semiconductor device of the first embodiment.

FIG. 21 is a sectional view (18/18) illustrating the method for manufacturing the semiconductor device of the first embodiment.

FIGS. 22A to 22C are sectional views (1/2) illustrating details of the method for manufacturing the semiconductor device of the first embodiment.

FIGS. 23A to 23D are sectional views (2/2) illustrating details of the method for manufacturing the semiconductor device of the first embodiment.

FIGS. 24A and 24B are sectional views illustrating further details of the method for manufacturing the semiconductor device of the first embodiment.

### DETAILED DESCRIPTION

Embodiments provide a semiconductor device and a method for manufacturing the same that enable suitably forming a high-concentration impurity layer in a semiconductor layer.

In general, according to one embodiment, a method for manufacturing a semiconductor device is disclosed. The method includes forming a hole through a first film; forming a semiconductor layer along a side surface of the hole; forming a second film overlaying a first region of the semiconductor layer; forming a third film along a side surface of a second region of the semiconductor layer that is above the first region; removing the second film to expose a side surface of the first region; forming a fourth film containing a plurality of first atoms and disposed along the side surface of the first region of the semiconductor layer; and diffusing the first atoms into the first region of the semiconductor layer.

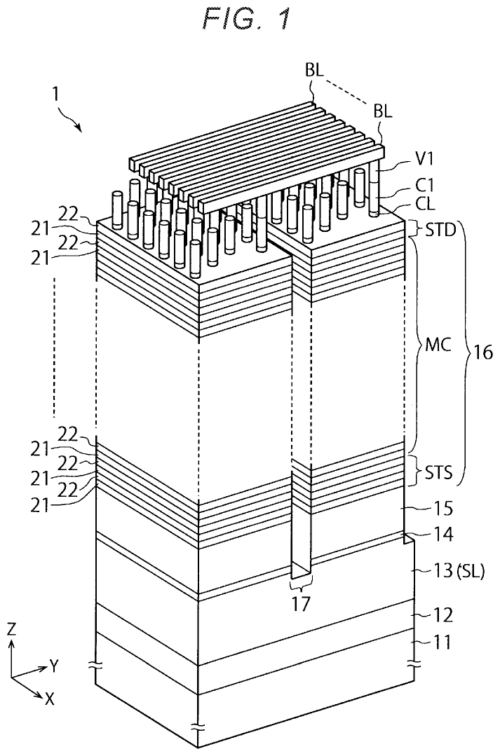

Hereinafter, embodiments of the present disclosure will be described with reference to the drawings. In FIGS. 1 to 24B, the same components are denoted by the same reference numerals, and redundant description will be omitted.

### First Embodiment

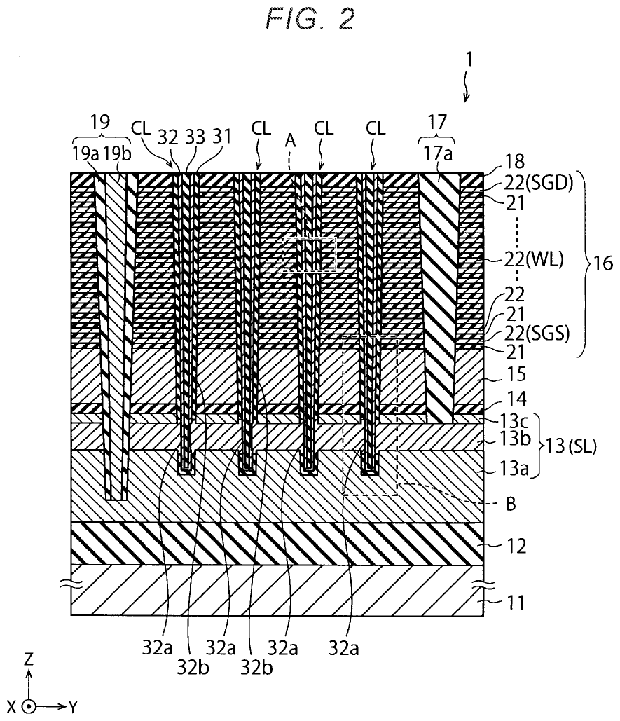

FIGS. 1 and 2 are respectively a perspective view and a sectional view illustrating a structure of a semiconductor device of a first embodiment. The semiconductor device of this embodiment includes a three-dimensional memory, such as a NAND flash memory. FIGS. 1 and 2 illustrate a memory cell array 1 in the three-dimensional memory.

The semiconductor device of this embodiment includes a substrate 11, an insulating film 12, a source layer 13, an insulating film 14, a gate layer 15, a stacked film 16, an element isolation part 17, an insulating film 18, a wiring part 19, a plurality of columnar parts CL, a plurality of contact plugs C1, and a plurality of via plugs V1 (FIGS. 1 and 2). The stacked film 16 includes a plurality of insulating films 21 and a plurality of electrode layers 22. Each columnar part CL includes a memory insulating film 31, a channel semiconductor layer 32, and a core insulating film 33.

As illustrated in FIG. 2, the source layer 13 includes semiconductor layers 13a to 13c. The element isolation part 17 includes an insulating film 17a. The wiring part 19 includes an insulating film 19a and a wiring layer 19b. The channel semiconductor layer 32 in each columnar part CL includes a lower layer 32a and an upper layer 32b.

FIG. 1 also illustrates a source line SL and a plurality of bit lines BL. FIG. 1 further illustrates areas where a plurality of memory cells MC, a plurality of source-side select transistors STS, and a plurality of drain-side select transistors STD are provided in the stacked film 16. FIG. 2 also illustrates a plurality of word lines WL, one or more source-side select gates SGS, and one or more drain-side select gates SGD provided in the stacked film 16. As illustrated in FIGS. 1 and 2, the source line SL is formed of the source layer 13, and each of the word line WL, the source-side select gate SGS, and the drain-side select gate SGD is formed of the electrode layer 22.

Hereinafter, the structure of the semiconductor device of this embodiment will be described with reference mainly to FIG. 2. In this description, FIG. 1 is also referred to, as appropriate.

The substrate 11 is a semiconductor substrate, such as a silicon (Si) substrate. FIG. 2 illustrates an X direction and a Y direction being parallel to a surface of the substrate 11 and being perpendicular to each other and a Z direction being perpendicular to the surface of the substrate 11. In this specification, a +Z direction is treated as an upward direction, and a −Z direction is treated as a downward direction. The −Z direction may or may not coincide with the direction of gravity.

The insulating film 12, the source layer 13, the insulating film 14, the gate layer 15, the stacked film 16, and the insulating film 18 are provided in this order on the substrate 11. The element isolation part 17, the wiring part 19, and each columnar part CL are provided in the source layer 13, the insulating film 14, the gate layer 15, the stacked film 16, and the insulating film 18. The set of the source layer 13, the insulating film 14, the gate layer 15, the stacked film 16, and the insulating film 18 is an example of a first film.

The source layer 13 includes semiconductor layers 13a to 13c that are provided in this order on the substrate 11 via the insulating film 12. The semiconductor layers 13a to 13c are, for example, polysilicon layers. The semiconductor layers 13a to 13c may or may not contain n-type or p-type impurity atoms. The semiconductor layers 13a to 13c are, for example, n-type semiconductor layers containing phosphorus (P) atoms or arsenic (As) atoms. The source layer 13 is an example of a first electrode layer.

The gate layer 15 is provided on the source layer 13 via the insulating film 14. The gate layer 15 is, for example, a semiconductor layer or a metal layer.

The stacked film 16 includes a plurality of insulating films 21 and a plurality of electrode layers 22 that are alternately provided on the gate layer 15. These electrode layers 22 are mutually separated in the Z direction. Each electrode layer 22 is, for example, a metal layer having a barrier metal layer, such as a titanium (Ti) layer or a titanium nitride (TiN) film, and having an electrode material layer, such as a tungsten (W) layer or a molybdenum (Mo) layer. Each electrode layer 22 is an example of a second electrode layer. On the other hand, each insulating film 21 is, for example, a silicon oxide film (SiO₂ film). The stacked film 16 is provided between the gate layer 15 and the insulating film 18.

The element isolation part 17 includes the insulating film 17a that is provided in the semiconductor layer 13c, the insulating film 14, the gate layer 15, the stacked film 16, and the insulating film 18. The element isolation part 17 has a plate shape extending in the X direction, as illustrated in FIG. 1. The element isolation part 17 separates the stacked film 16 and the gate layer 15 into a plurality of blocks (or fingers).

The wiring part 19 includes the insulating film 19a and the wiring layer 19b that are provided in this order in the semiconductor layers 13a to 13c, the insulating film 14, the gate layer 15, the stacked film 16, and the insulating film 18. The wiring part 19 has a plate shape extending in the X direction, as in the case of the element isolation part 17. The wiring part 19 separates the stacked film 16 and the gate layer 15 into a plurality of blocks (or fingers). The wiring layer 19b is, for example, a semiconductor layer or a metal layer. The wiring layer 19b is electrically insulated from each electrode layer 22 and the gate layer 15 by the insulating film 19a but is electrically connected to the source layer 13 in the vicinity of a lower end of the wiring part 19.

Each columnar part CL includes the memory insulating film 31, the channel semiconductor layer 32, and the core insulating film 33 that are provided in this order in the semiconductor layers 13a to 13c, the insulating film 14, the gate layer 15, the stacked film 16, and the insulating film 18. FIG. 1 illustrates a plurality of columnar parts CL that are arranged in a two-dimensional array in a plane view. Each columnar part CL has a columnar shape extending in the Z direction. The planar shape of each columnar part CL is, for example, a circle.

The memory insulating film 31 includes a block insulating film, a charge storage layer, and a tunnel insulating film, which will be described later. The block insulating film is, for example, a SiO₂ film. The charge storage layer is, for example, a silicon nitride film (SiN film). The charge storage layer is able to accumulate signal charges. The tunnel insulating film is, for example, a SiO₂ film or a silicon oxynitride film (SiON film). The memory insulating film 31 has a tubular shape extending in the Z direction and includes an inner circumferential side surface and an outer circumferential side surface.

The channel semiconductor layer 32 is, for example, a polysilicon layer. The channel semiconductor layer 32 of this embodiment contains n-type or p-type impurity atoms and contains P atoms, for example. The P atom in the channel semiconductor layer 32 is an example of a first atom. The channel semiconductor layer 32 has a tubular shape extending in the Z direction and includes an inner circumferential side surface and an outer circumferential side surface.

The core insulating film 33 is, for example, a SiO₂ film. The core insulating film 33 has a columnar shape extending in the Z direction and includes a side surface in contact with the channel semiconductor layer 32.

The channel semiconductor layer 32 in each columnar part CL is in contact with the semiconductor layer 13b at the side surface of each columnar part CL and is thereby electrically connected to the source layer 13 (source line SL). The channel semiconductor layer 32 in each columnar part CL is electrically connected also to a corresponding bit line BL via one contact plug C1 and one via plug V1 (FIG. 1).

The channel semiconductor layer 32 in each columnar part CL includes the lower layer 32a and the upper layer 32b. The lower layer 32a is provided in the vicinity of the lower end of each columnar part CL. The upper layer 32b is provided above the lower layer 32a. In this embodiment, the lower layer 32a is a high-concentration impurity layer containing a high concentration of P atoms, and the upper layer 32b is a low-concentration impurity layer containing a low concentration of P atoms. Thus, the concentration of P atoms in the upper layer 32b is lower than that in the lower layer 32a. The concentration of P atoms in the lower layer 32a is, for example, 1.0×10²⁰ atoms/cm³ or higher. The concentration of P atoms in the upper layer 32b is, for example, 1.0×10¹⁷ atoms/cm³ or lower. The lower layer 32a and the upper layer 32b are examples of first and second parts, respectively. The concentrations of P atoms in the lower layer 32a and the upper layer 32b are examples of first and second concentrations, respectively. Further details of the lower layer 32a and the upper layer 32b will be described later.

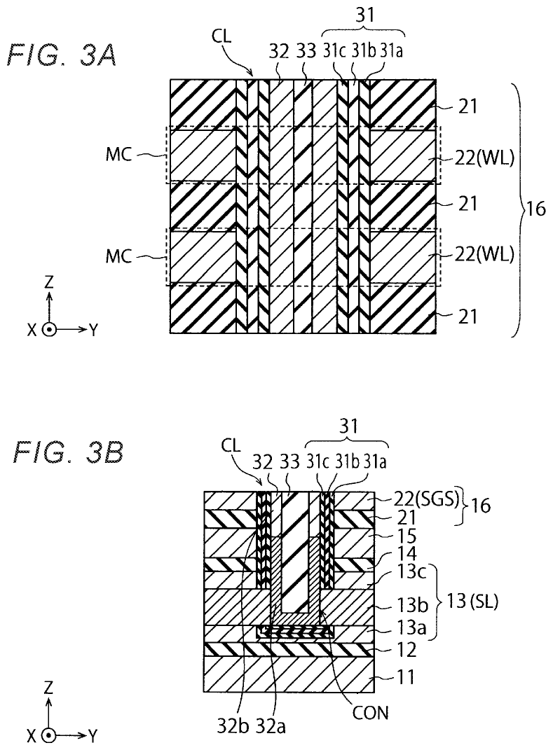

FIGS. 3A and 3B are enlarged sectional views illustrating structures of the semiconductor device of the first embodiment.

FIG. 3A is an enlarged view of a region “A” illustrated in FIG. 2. As described above, the memory insulating film 31 in each columnar part CL includes a block insulating film 31a, a charge storage layer 31b, and a tunnel insulating film 31c.

FIG. 3B is an enlarged view of a region “B” illustrated in FIG. 2. As described above, the channel semiconductor layer 32 in each columnar part CL includes the lower layer 32a and the upper layer 32b. The lower layer 32a is provided in the vicinity of the lower end of each columnar part CL. The upper layer 32b is provided above the lower layer 32a. The lower layer 32a is provided at the same height as those of the source layer 13 and so on, and the upper layer 32b is provided at the same height as those of the stacked film 16 and so on.

The channel semiconductor layer 32 has a connection part CON that is connected to the source layer 13, as illustrated in FIG. 3B. The channel semiconductor layer 32 is in contact with the source layer 13 at the connection part CON. The connection part CON is positioned in the vicinity of the outer circumferential side surface of the channel semiconductor layer 32, at the side of the lower layer 32a. The connection part CON is an example of a third part.

The P atoms in the lower layer 32a of this embodiment are implanted in the lower layer 32a from the inner circumferential side surface thereof, as described later. Due to this, the concentration of P atoms in this embodiment is high in the vicinity of the inner circumferential side surface of the lower layer 32a and is low in the vicinity of the outer circumferential side surface of the lower layer 32a. As a result, the concentration of P atoms in the connection part CON is lower than that of other part in the lower layer 32a. The concentration of P atoms in the connection part CON is an example of a third concentration.

The channel semiconductor layer 32 of this embodiment has a sharp concentration gradient of P atoms between the lower layer 32a and the upper layer 32b. With this structure, GIDL that causes deletion of storage data of the three-dimensional memory efficiently occurs. The deletion operation of the three-dimensional memory of this embodiment is performed by using this GIDL. It is noted that the channel semiconductor layer 32 may contain impurity atoms (e.g., As atoms) other than P atoms.

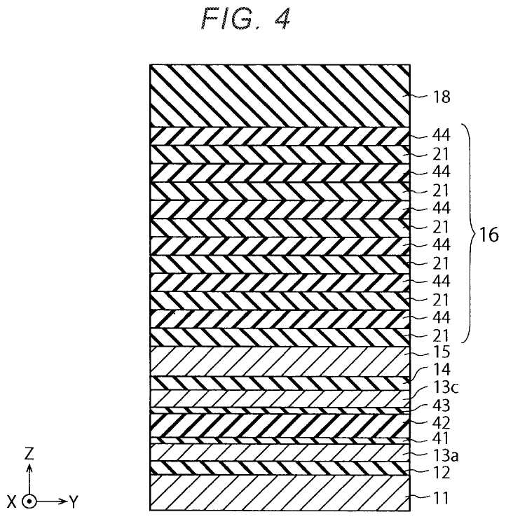

The semiconductor device of this embodiment is manufactured by the method illustrated in FIGS. 4 to 24B, which will be described later. This method facilitates forming the channel semiconductor layer 32 having a sharp concentration gradient of P atoms, even when a memory hole for the columnar part CL has a high aspect ratio.

FIGS. 4 to 21 are sectional views illustrating a method for manufacturing the semiconductor device of the first embodiment.

First, the insulating film 12, the semiconductor layer 13a, a protective film 41, a sacrificial layer 42, a protective film 43, the semiconductor layer 13c, the insulating film 14, the gate layer 15, the stacked film 16, and the insulating film 18 are formed on the substrate 11, in this order (FIG. 4). The stacked film 16 is formed so as to alternately include a plurality of insulating films 21 and a plurality of sacrificial layers 44. The set of the semiconductor layer 13a, the protective film 41, the sacrificial layer 42, the protective film 43, the semiconductor layer 13c, the insulating film 14, the gate layer 15, the stacked film 16, and the insulating film 18 is an example of a first film. The sacrificial layer 42 is an example of a first layer. Each sacrificial layer 44 is an example of a second layer.

The semiconductor layer 13a is, for example, an n-type polysilicon layer containing P atoms. The protective film 41 is, for example, a SiO₂ film. The sacrificial layer 42 is, for example, a SiN film. The protective film 43 is, for example, a SiO₂ film. The semiconductor layer 13c is, for example, an undoped polysilicon layer or an n-type polysilicon layer containing P atoms. The insulating film 14 is, for example, a SiO₂ film. The gate layer 15 is, for example, a semiconductor layer or a metal layer. Each insulating film 21 is, for example, a SiO₂ film. Each sacrificial layer 44 is, for example, a SiN film. The insulating film 18 is, for example, a SiO₂ film. The thicknesses of the semiconductor layer 13a, the sacrificial layer 42, the semiconductor layer 13c, and the gate layer 15 are respectively approximately 200 nm, approximately 30 nm, approximately 30 nm, and approximately 200 nm, for example.

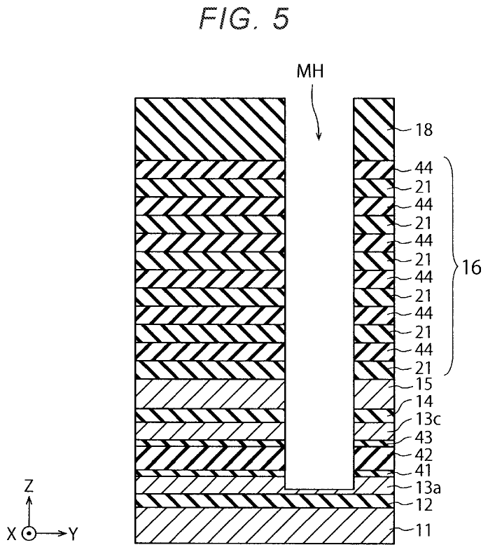

Next, a plurality of memory holes MH are formed in the insulating film 18, the stacked film 16, the gate layer 15, the insulating film 14, the semiconductor layer 13c, the protective film 43, the sacrificial layer 42, the protective film 41, and the semiconductor layer 13a, by lithography and reactive ion etching (RIE) (FIG. 5). FIG. 5 illustrates an example of one of these memory holes MH. In forming these memory holes MH, the stacked film 16 is etched, for example, by using CF gas (“C” represents carbon, and “F” represents fluorine).

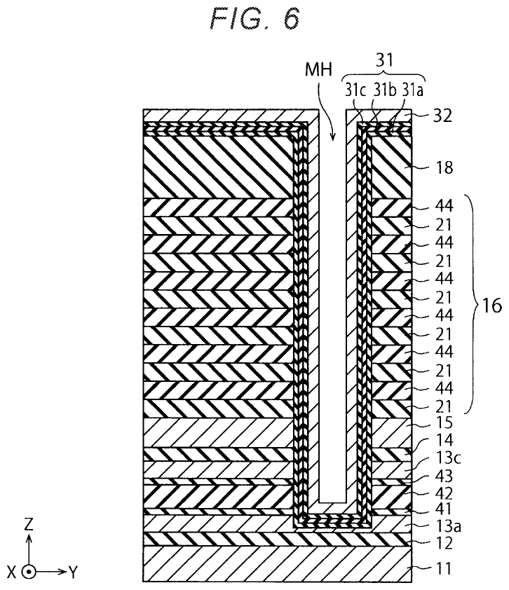

Then, the block insulating film 31a, the charge storage layer 31b, the tunnel insulating film 31c, and the channel semiconductor layer 32 are formed on the whole surface of the substrate 11, in this order (FIG. 6). As a result, the block insulating film 31a, the charge storage layer 31b, the tunnel insulating film 31c, and the channel semiconductor layer 32 are conformally formed on side surfaces of the insulating film 18, the stacked film 16, the gate layer 15, the insulating film 14, the semiconductor layer 13c, the protective film 43, the sacrificial layer 42, the protective film 41, and the semiconductor layer 13a and on an upper surface of the semiconductor layer 13a, in each memory hole MH. The channel semiconductor layer 32 that is formed in the process illustrated in FIG. 6 is, for example, an undoped polysilicon layer that does not contain intentionally doped n-type or p-type impurity atoms.

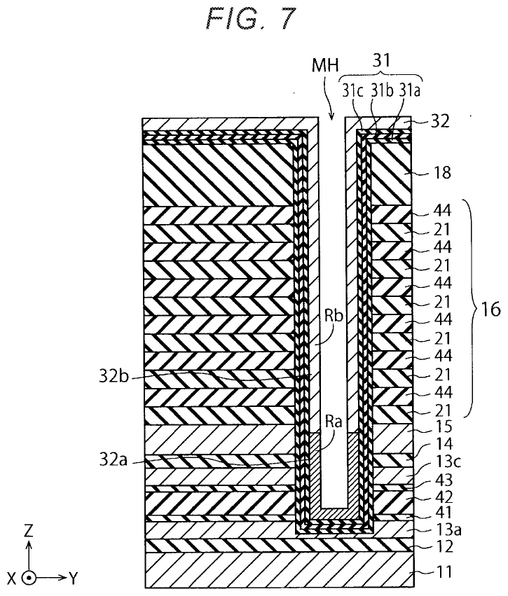

Thereafter, n-type or p-type impurity atoms are selectively implanted in a partial region of the channel semiconductor layer 32 (FIG. 7). FIG. 7 illustrates a lower region Ra and an upper region Rb of the channel semiconductor layer 32. The lower region Ra is positioned in the vicinity of the bottom surface of each memory hole MH, and the upper region Rb is positioned above the lower region Ra. In the process illustrated in FIG. 7, n-type or p-type impurity atoms are implanted in the lower region Ra, which is selected between the lower region Ra and the upper region Rb. The lower region Ra and the upper region Rb are respectively examples of first and second regions. The impurity atoms that are implanted in the process illustrated in FIG. 7 are, for example, P atoms.

In this embodiment, due to selective implantation of P atoms, a large amount of P atoms are implanted in the lower region Ra, but P atoms are hardly implanted in the upper region Rb. As a result, the lower layer 32a, which is a high-concentration impurity layer, is formed in the lower region Ra, and the upper layer 32b, which is a low-concentration impurity layer, is formed in the upper region Rb. The concentration of P atoms in the upper layer 32b is lower than that in the lower layer 32a. The concentration of P atoms in the lower layer 32a is, for example, 1.0×10²⁰ atoms/cm³ or higher. The concentration of P atoms in the upper layer 32b is, for example, 1.0×10¹⁷ atoms/cm³ or lower. The lower layer 32a and the upper layer 32b are examples of first and second parts, respectively. The concentrations of P atoms in the lower layer 32a and the upper layer 32b are examples of first and second concentrations, respectively. The lower layer 32a is formed on the bottom surface and the side surface of each memory hole MH, and the upper layer 32b is formed above the lower layer 32a, on the side surface of each memory hole MH.

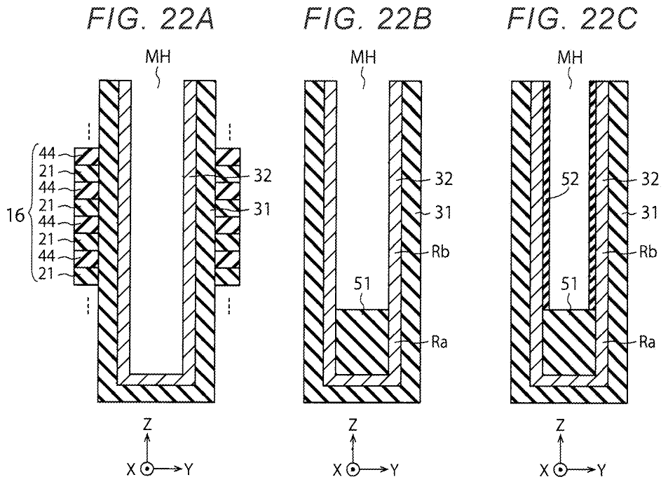

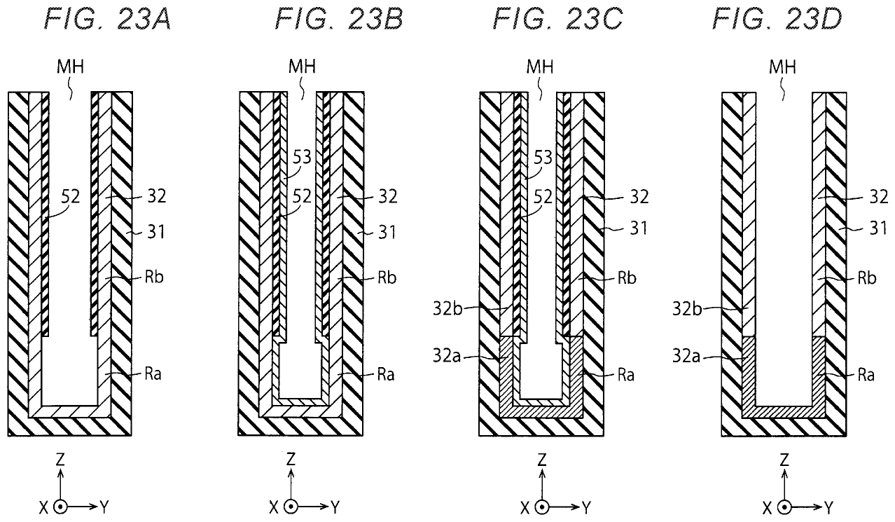

It is noted that the P atoms in the upper layer 32b may be implanted therein in the process illustrated in FIG. 7 or in another process. In addition, in the process illustrated in FIG. 7, a small amount of P atoms may be implanted in the upper region Rb, or no P atoms may be implanted at all in the upper region Rb. Further details of the process illustrated in FIG. 7 will be described later with reference to FIGS. 22A to 23D.

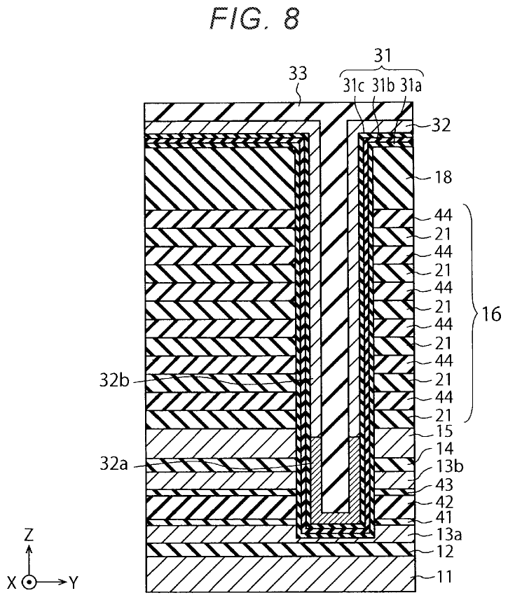

Next, the core insulating film 33 is formed on the whole surface of the substrate 11 (FIG. 8). As a result, the core insulating film 33 is formed on the side surface and the upper surface of the channel semiconductor layer 32 in each memory hole MH and fills the space in each memory hole MH.

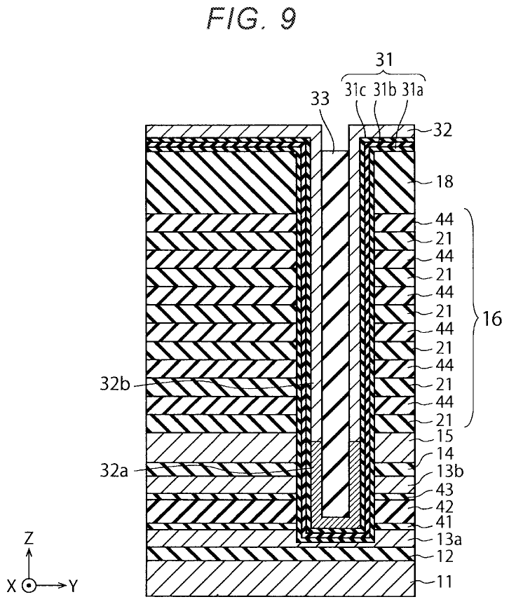

Then, the core insulating film 33 is etched back (FIG. 9). This removes the core insulating film 33 outside the memory hole MH, whereby the channel semiconductor layer 32 is exposed again.

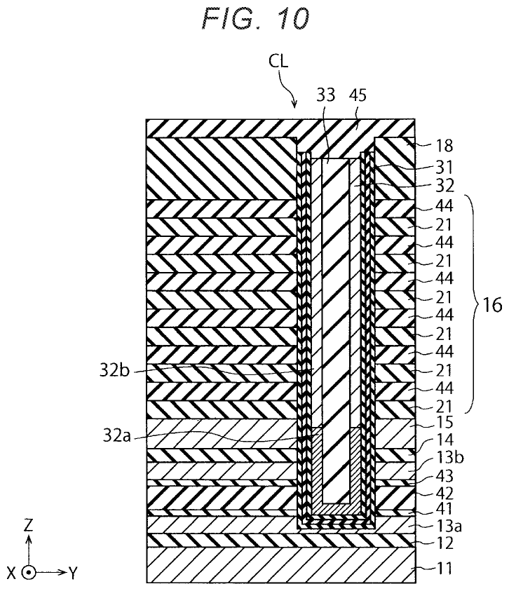

Subsequently, after the channel semiconductor layer 32 and the memory insulating film 31 outside the memory hole MH are removed, a cap film 45 is formed on the memory insulating film 31, the channel semiconductor layer 32, and the core insulating film 33 (FIG. 10). Thus, the columnar part CL that is formed in each memory hole MH is covered with the cap film 45.

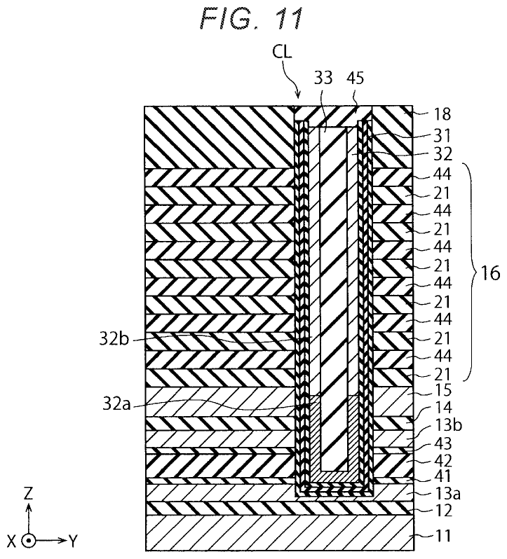

Next, an upper surface of the cap film 45 is processed by RIE (FIG. 11). This divides the cap film 45 into a plurality of parts in such a manner as to remain on individual columnar parts CL, whereby the upper surface of the insulating film 18 is exposed again.

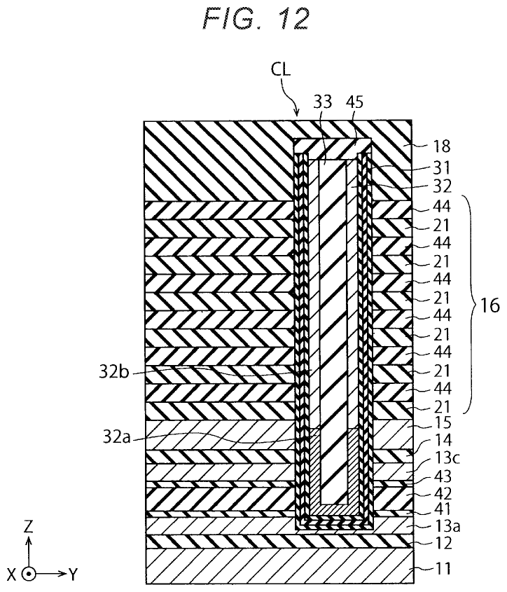

Thereafter, an additional insulating film 18 is formed on the cap film 45 and the already existing insulating film 18 (FIG. 12). Thus, each columnar part CL is covered with the additional insulating film 18 via the cap film 45. The additional insulating film 18 is, for example, a SiO₂ film.

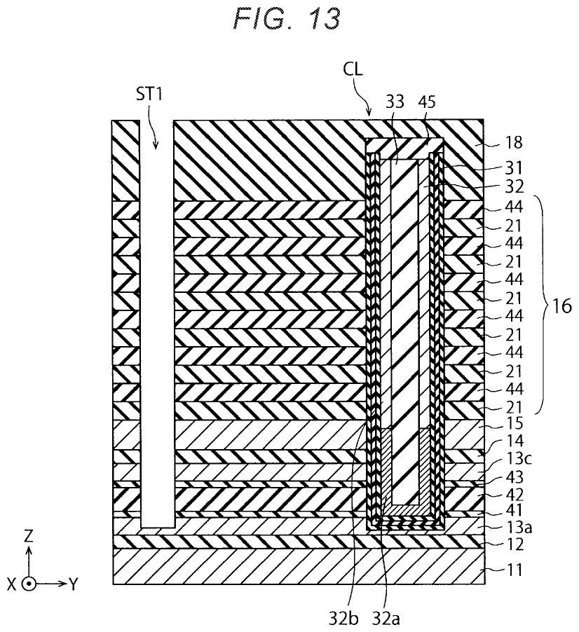

Next, a plurality of slits ST1 are formed in the insulating film 18, the stacked film 16, the gate layer 15, the insulating film 14, the semiconductor layer 13c, the protective film 43, the sacrificial layer 42, the protective film 41, and the semiconductor layer 13a, by lithography and RIE (FIG. 13). FIG. 13 illustrates an example of one of these slits ST1. These slits ST1 are formed so as to have a shape extending in the X direction.

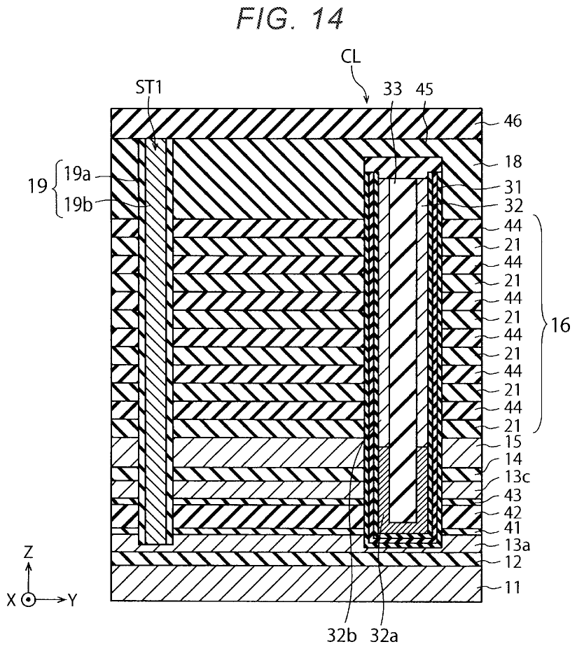

Subsequently, after the insulating film 19a is formed on the side surface and the bottom surface of each slit ST1, the insulating film 19a is removed from the bottom surface of each slit ST1, and the wiring layer 19b is formed in each slit ST1 (FIG. 14). As a result, the wiring part 19 is formed in each slit ST1.

Thereafter, an insulating film 46 is formed on each wiring part 19 and on the insulating film 18 (FIG. 14). The insulating film 46 is, for example, a SiO₂ film.

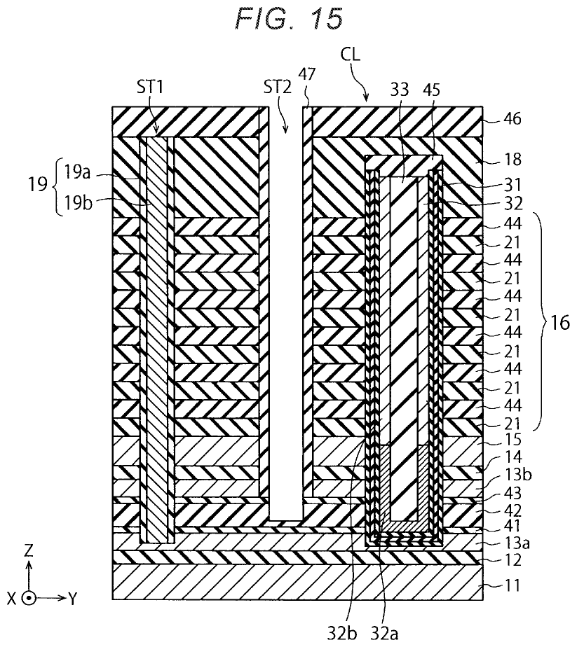

Next, a plurality of slits ST2 are formed in the insulating film 46, the insulating film 18, the stacked film 16, the gate layer 15, the insulating film 14, the semiconductor layer 13c, and the protective film 43, by lithography and RIE (FIG. 15). FIG. 15 illustrates an example of one of these slits ST2. These slits ST2 are formed so as to have a shape extending in the X direction.

Subsequently, after an insulating film 47 is formed on the side surface and the bottom surface of each slit ST2, the insulating film 47 is removed from the bottom surface of each slit ST2, and the sacrificial layer 42 that is exposed at the bottom surface of each slit ST2 is etched (FIG. 15). The insulating film 47 is, for example, a SiN film.

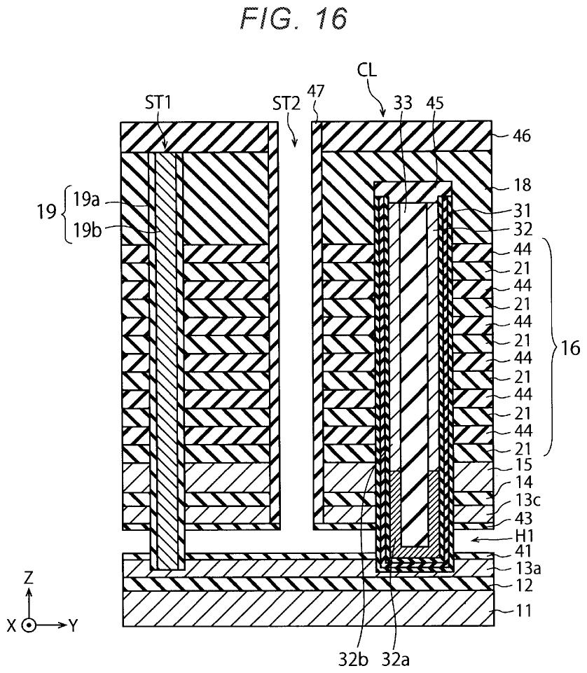

Next, the sacrificial layer 42 is removed through each slit ST2 by wet etching (FIG. 16). This forms a cavity H1 between the protective films 41 and 43. In the case of using a SiN film as the sacrificial layer 42, wet etching is performed, for example, by using hot phosphoric acid.

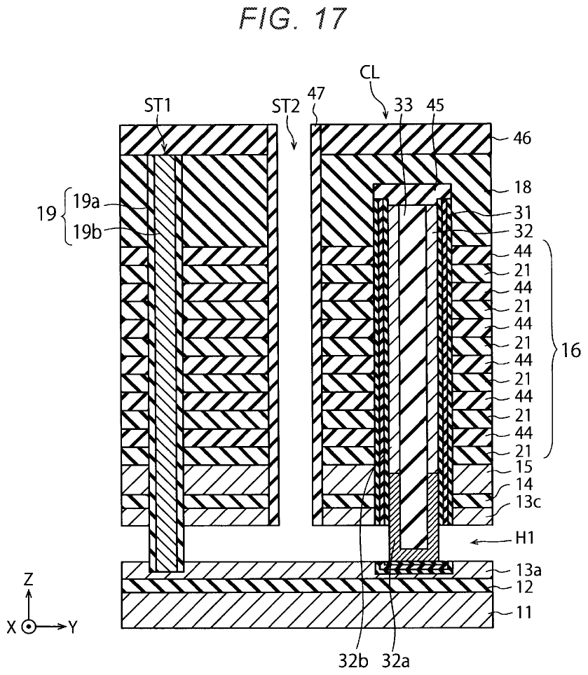

Thereafter, isotropic etching is performed through each slit ST2 and the cavity H1 to remove a part of the memory insulating film 31 in each columnar part CL (FIG. 17). Specifically, the part that is exposed in the cavity H1 of the memory insulating film 31 is removed. This causes the outer circumferential side surface of the channel semiconductor layer 32 (lower layer 32a) of each columnar part CL to be exposed in the cavity H1. In the process illustrated in FIG. 17, the protective films 41 and 43 are also removed. Isotropic etching is performed, for example, by chemical dry etching (CDE).

In this embodiment, each of the charge storage layer 31b and the insulating film 47 is a SiN film. Nevertheless, the insulating film 47, which is thicker than the charge storage layer 31b, remains, whereas the charge storage layer 31b that is exposed in the cavity H1 is removed, in the process illustrated in FIG. 17.

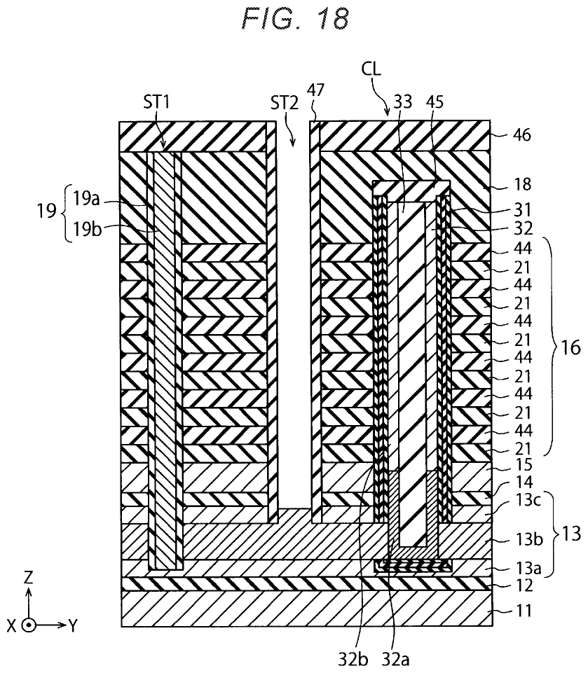

Then, the semiconductor layer 13b is formed in the cavity H1 by epitaxial growth from the semiconductor layers 13a and 13c (FIG. 18). Thus, the source layer 13 is formed between the insulating films 12 and 14. In this manner, the sacrificial layer 42 is replaced with the semiconductor layer 13b. The semiconductor layer 13b is, for example, a polysilicon layer containing P atoms. The semiconductor layer 13b is formed, for example, by supplying silicon-containing gas into the cavity H1 from each slit ST2.

The channel semiconductor layer 32 of each columnar part CL comes into contact with the semiconductor layer 13b at the outer circumferential side surface, which is exposed in the cavity H1, of the channel semiconductor layer 32. Specifically, the channel semiconductor layer 32 in each columnar part CL is in contact with the semiconductor layer 13b at the connection part CON illustrated in FIG. 3B. Thus, the channel semiconductor layer 32 in each columnar part CL is electrically connected to the source layer 13. The connection part CON is an example of a third part.

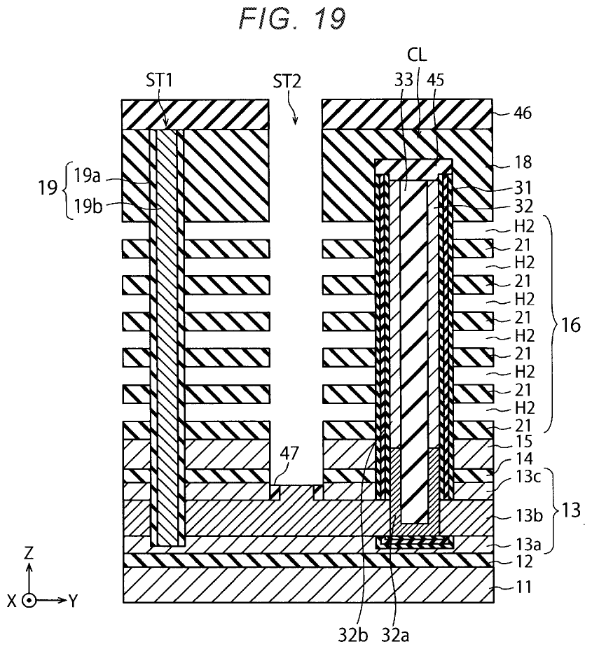

Subsequently, after the insulating film 47 is removed to expose the stacked film 16, each sacrificial layer 44 is removed from the stacked film 16 (FIG. 19). As a result, a plurality of cavities H2 are formed in the stacked film 16. In the process illustrated in FIG. 19, the insulating film 47 and each sacrificial layer 44 are removed by etching gas or etching solution (e.g., hot phosphoric acid solution) that is supplied to each slit ST2.

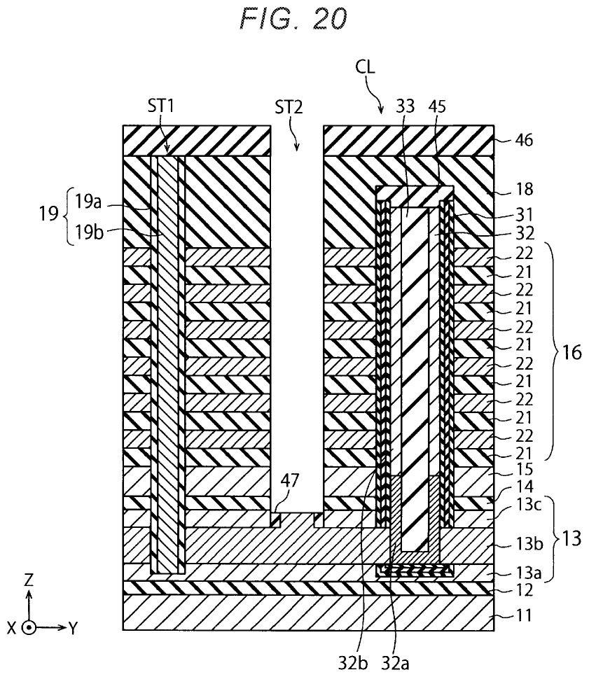

Next, a plurality of electrode layers 22 are embedded in these cavities H2 through each slit ST2 (FIG. 20). This forms the stacked film 16 that includes a plurality of insulating films 21 and a plurality of electrode layers 22 in an alternate manner. In this manner, the plurality of the sacrificial layers 44 are replaced with the plurality of the electrode layers 22. These electrode layers 22 are formed, for example, by chemical vapor deposition (CVD) in which source gas is supplied from each slit ST2.

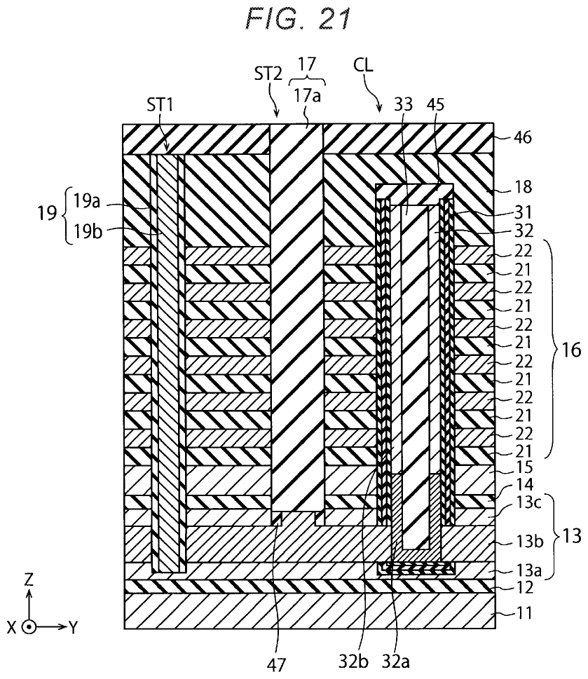

Next, the insulating film 17a is embedded in each slit ST2 (FIG. 21). As a result, the element isolation part 17 is formed in each slit ST2.

Thereafter, a plurality of contact plugs C1, a plurality of via plugs V1, a plurality of bit lines BL, and so on are formed above the substrate 11 (refer to FIG. 1). Thus, the semiconductor device of this embodiment is manufactured.

FIGS. 22A to 23D are sectional views illustrating details of the method for manufacturing the semiconductor device of the first embodiment. FIGS. 22A to 23D illustrate details of the process in FIG. 7.

FIG. 22A illustrates the memory hole MH immediately before start of the process in FIG. 7. Specifically, FIG. 22A illustrates the memory hole MH that is formed in the stacked film 16 and so on, and the memory insulating film 31 and the channel semiconductor layer 32 that are formed, in this order, on the side surface and the bottom surface of the memory hole MH. The channel semiconductor layer 32 illustrated in FIG. 22A is, for example, an undoped polysilicon layer that does not contain intentionally doped n-type or p-type impurity atoms. It is noted that illustration of the stacked film 16 is omitted in FIGS. 22B to 23D that are described below.

First, an organic film 51 is formed in the memory hole MH (FIG. 22B). The organic film 51 of this embodiment is formed only in the vicinity of the bottom surface of the memory hole MH so as to not fill up the whole space in the memory hole MH. As a result, the organic film 51 is formed in contact with the side surface and the upper surface of the lower region Ra of the channel semiconductor layer 32 but is not formed on the side surface of the upper region Rb of the channel semiconductor layer 32. The organic film 51 is an example of a second film.

The organic film 51 is, for example, a resist film that is formed by applying a liquid resist material. The resist material is applied, for example, by spin coating. The resist film may be formed by baking a resist material into a solid state or by naturally drying a resist material into a solid state. The position at which the organic film 51 is formed is controlled, for example, by adjusting the concentration of resin of the organic film 51. For example, the concentration of resin of the resist material may be increased or decreased before the resist material is applied, to raise or lower the height of the upper surface of the resist film formed of the resist material. This makes it possible to extend or narrow the area that will be the lower region Ra.

A native oxide film that is formed on the surface of the channel semiconductor layer 32 may be removed before the organic film 51 is formed. The native oxide film is removed, for example, by using diluted hydrofluoric acid (HF) solution.

Next, a chemical oxide film 52 is formed on the surface of the channel semiconductor layer 32 (FIG. 22C). At the time the process illustrated in FIG. 22C is performed, the side surface and the upper surface of the lower region Ra of the channel semiconductor layer 32 are covered with the organic film 51, whereas the side surface of the upper region Rb of the channel semiconductor layer 32 is not covered with the organic film 51. Thus, the chemical oxide film 52 is formed in contact with the side surface of the upper region Rb, but it is not formed on the side surface and the upper surface of the lower region Ra. The chemical oxide film 52 is an example of a third film.

The chemical oxide film 52 is, for example, a SiO₂ film. The chemical oxide film 52 is formed on the surface of the channel semiconductor layer 32 by using a chemical solution. This enables forming the oxide film (chemical oxide film 52) without placing the substrate 11 in a reaction furnace, which prevents the organic film 51 from being damaged by heat. The chemical solution is, for example, a hydrogen peroxide solution (H₂O₂) having a concentration of 0.1% or more. In this case, the chemical oxide film 52 can be formed by batch processing in which the substrate 11 is immersed in a hydrogen peroxide solution for approximately 10 minutes.

In the process illustrated in FIG. 22C, a spin-on-glass (SOG) film may be formed instead of the chemical oxide film 52. The SOG film is a SiO₂ film that is formed by coating. Also, in this case, it is possible to form the oxide film (SOG film) without placing the substrate 11 in a reaction furnace, which prevents the organic film 51 from being damaged by heat.

Next, the organic film 51 is removed from the memory hole MH (FIG. 23A). Thus, the side surface and the upper surface of the lower region Ra are exposed in the memory hole MH, again. The organic film 51 is removed, for example, by single wafer processing using a thinner. The organic film 51 of this embodiment is removed from the side surface and the upper surface of the lower region Ra so that the chemical oxide film 52 will remain on the side surface of the upper region Rb.

Then, a dopant film 53 is formed in the memory hole MH (FIG. 23B). The dopant film 53 of this embodiment contains a large number of n-type or p-type impurity atoms at high concentration. These impurity atoms are, for example, P atoms. The dopant film 53 is an example of a fourth film, and these impurity atoms are an example of first atoms.

The dopant film 53 is, for example, a P-containing film, which contains P atoms and is formed by spin coating. The P-containing film may be one of a conductor film, a semiconductor film, and an insulating film. An example of the P-containing film includes an SOG film containing P atoms. The P-containing film of this embodiment is conformally formed in the memory hole MH by applying a liquid that is a material of the dopant film 53. In this embodiment, the dopant film 53, which is a P-containing film, can be formed so as to have high stability even when the aspect ratio of the memory hole MH is high. In the process illustrated in FIG. 23B, the dopant film 53 is formed in direct contact with the side surface and the upper surface of the lower region Ra and is formed on the side surface of the upper region Rb via the chemical oxide film 52.

Thereafter, the dopant film 53 and so on are subjected to a heat treatment (FIG. 23C). This makes the P atoms in the dopant film 53 diffuse into the channel semiconductor layer 32. At this time, the chemical oxide film 52 prevents the P atoms in the dopant film 53 from diffusing into the channel semiconductor layer 32 therethrough. Thus, a large number of the P atoms diffuse into the lower region Ra, but the P atoms hardly diffuse into the upper region Rb. As a result, the lower layer 32a, which is a high-concentration impurity layer, is formed in the lower region Ra, and the upper layer 32b, which is a low-concentration impurity layer, is formed in the upper region Rb. The concentration of P atoms in the upper layer 32b is lower than that in the lower layer 32a. The concentration of P atoms in the lower layer 32a is, for example, 1.0×10²⁰ atoms/cm³ or higher. The concentration of P atoms in the upper layer 32b is, for example, 1.0×10¹⁷ atoms/cm³ or lower.

The heat treatment is performed, for example, by heating the dopant film 53 at 850° C. or higher in rapid thermal anneal (RTA). In this embodiment, the dopant film 53 is heated at such a high temperature, which enables sufficiently increasing the concentration of P atoms in the lower layer 32a. In one example, heating the dopant film 53 at 1000° C. or higher enables increasing the concentration of P atoms in the lower layer 32a to 1.0×10²⁰ to 1.0×10²¹ atoms/cm³.

The P atoms diffuse from the dopant film 53 and are implanted in the lower layer 32a, and thus, they are implanted in the lower layer 32a from the inner circumferential side surface thereof. Due to this, the concentration of P atoms in this embodiment is high in the vicinity of the inner circumferential side surface of the lower layer 32a and is low in the vicinity of the outer circumferential side surface of the lower layer 32a. As a result, the concentration of P atoms in the connection part CON (refer to FIG. 3B) is lower than that of other part in the lower layer 32a.

It is noted that P atoms may be implanted in the upper layer 32b by diffusion from the dopant film 53 in the process illustrated in FIG. 23C or in another process. For example, P atoms may be implanted in the upper layer 32b due to diffusion from the lower layer 32a. In addition, in the process illustrated in FIG. 23C, a small amount of P atoms may be implanted in the upper region Rb, or no P atoms may be implanted at all in the upper region Rb. In other words, the upper layer 32b may be an n-type or p-type semiconductor layer or a neutral semiconductor layer. That is, the concentration of P atoms in the upper layer 32b may be zero or a value other than zero.

Then, the chemical oxide film 52 and the dopant film 53 are removed from the memory hole MH (FIG. 23D). Thus, the side surface and the upper surface of the channel semiconductor layer 32 are exposed in the memory hole MH, again. The chemical oxide film 52 and the dopant film 53 are removed, for example, by using diluted hydrofluoric acid solution.

Herein, further details of the chemical oxide film 52 and the dopant film 53 will be described.

The chemical oxide film 52 of this embodiment prevents the P atoms in the dopant film 53 from diffusing into the channel semiconductor layer 32 therethrough. In general, a SiO₂ film, which is an example of the chemical oxide film 52, can prevent P atoms from passing therethrough. In view of this, in this embodiment, the chemical oxide film 52 is used as a film interposed between the upper region Rb and the dopant film 53, which makes it possible to prevent diffusion of P atoms from the dopant film 53 to the upper region Rb. The film that is interposed between the upper region Rb and the dopant film 53 may be a film other than the chemical oxide film 52, on the condition that it can prevent diffusion of P atoms. However, desirably, this film is not removed or hardly removed by a substance for removing the organic film 51 (e.g., thinner).

The liquid that is a material of the dopant film 53 may contain various substances. This liquid may contain, for example an impurity diffusion component, an amine compound, and an organic solvent. The impurity diffusion component is a component for diffusing n-type or p-type impurity atoms into the channel semiconductor layer 32 and is, for example, a phosphorus (P) compound, an arsenic (As) compound, or a boron (B) compound. An example of the amine compound includes an aliphatic amine compound containing at least one of a primary amino group, a secondary amino group, and a tertiary amino group. The organic solvent is, for example, one of esters.

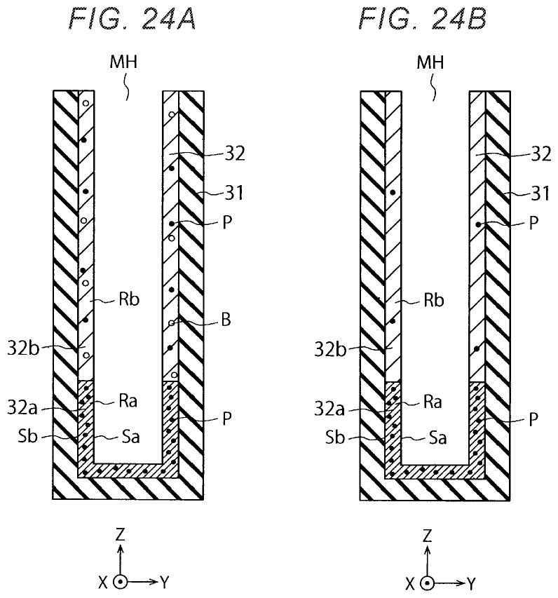

FIGS. 24A and 24B are sectional views illustrating further details of the method for manufacturing the semiconductor device of the first embodiment.

FIG. 24A illustrates a channel semiconductor layer 32 of a semiconductor device of a comparative example. The filled circles in the channel semiconductor layer 32 represent phosphorous (P) atoms, whereas the open circles in the channel semiconductor layer 32 represent boron (B) atoms. FIG. 24A also illustrates an inner circumferential side surface Sa and an outer circumferential side surface Sb of the channel semiconductor layer 32.

The channel semiconductor layer 32 of this comparative example contains P atoms at high concentration in the lower layer 32a and contains P atoms and B atoms in the upper layer 32b. The lower layer 32a and the upper layer 32b of this comparative example are formed by diffusing P atoms into the lower region Ra and the upper region Rb and then diffusing B atoms into the upper region Rb. Thus, the effects of the P atoms in the upper region Rb are canceled by the B atoms, whereby a sharp concentration gradient of P atoms is achieved. However, this comparative example requires implanting B atoms as well as P atoms, in the channel semiconductor layer 32.

On the other hand, FIG. 24B illustrates the channel semiconductor layer 32 of the semiconductor device of this embodiment. In this embodiment, P atoms are diffused from the dopant film 53 into the channel semiconductor layer 32, in the state in which the upper region Rb is covered with the chemical oxide film 52. With this process, it is possible to diffuse P atoms so as to produce a large difference in concentration of P atoms between the lower layer 32a and the upper layer 32b. Thus, this embodiment enables achieving a sharp concentration gradient of P atoms without implanting B atoms in the channel semiconductor layer 32.

The P atoms in the lower layer 32a of this embodiment diffuse from the dopant film 53 and are implanted in the lower layer 32a, and thus, they are implanted in the lower layer 32a from the inner circumferential side surface Sa thereof. The diffusion amount of P atoms can be increased, for example, by thickening the dopant film 53 or increasing the RTA temperature.

As described above, the channel semiconductor layer 32 of this embodiment has a sharp concentration gradient of P atoms between the lower layer 32a and the upper layer 32b. Thus, in this embodiment, GIDL that is used in operation of the semiconductor device efficiently occurs. This prevents trapping of holes that are generated by GIDL as well as deterioration of cut-off characteristics at the time of boosting.

The lower layer 32a and the upper layer 32b of this embodiment are formed by diffusing P atoms from the dopant film 53 into the channel semiconductor layer 32, in the state in which the upper region Rb is covered with the chemical oxide film 52. Thus, this embodiment enables achieving a sharp concentration gradient of P atoms without implanting B atoms in the channel semiconductor layer 32. Moreover, the lower layer 32a and the upper layer 32b can be formed while reducing damage to the channel semiconductor layer 32 due to implantation of the impurity atoms.

In this manner, this embodiment makes it possible to suitably form the lower layer 32a and the upper layer 32b in the channel semiconductor layer 32. For example, using an appropriate dopant film 53 enables forming desirable lower layer 32a and upper layer 32b, even when the aspect ratio of the memory hole MH is high.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method for manufacturing a semiconductor device, comprising:
forming a hole through a first film;
forming a semiconductor layer along a side surface of the hole;
forming a second film overlaying a first region of the semiconductor layer;
forming a third film along a side surface of a second region of the semiconductor layer that is above the first region;
removing the second film to expose a side surface of the first region;
forming a fourth film containing a plurality of first atoms and disposed along the side surface of the first region of the semiconductor layer; and
diffusing the first atoms into the first region of the semiconductor layer.

2. The method for manufacturing a semiconductor device according to claim 1, wherein the first film includes:
a first layer to be replaced with a first electrode layer; and
a plurality of second layers that are formed in a manner separated from each other above the first region and that are to be replaced with a plurality of second electrode layers, respectively.

3. The method for manufacturing a semiconductor device according to claim 1, wherein the second film is removed while the third film remains extending along the side surface of the second region.

4. The method for manufacturing a semiconductor device according to claim 1, wherein the second film includes an organic film formed by applying a liquid.

5. The method for manufacturing a semiconductor device according to claim 4, wherein a position of the organic film is controlled by adjusting a concentration of resin of the organic film.

6. The method for manufacturing a semiconductor device according to claim 4, wherein the organic film is removed using a thinner.

7. The method for manufacturing a semiconductor device according to claim 1, wherein the third film includes at least one of a chemical oxide film or a coated film.

8. The method for manufacturing a semiconductor device according to claim 1, wherein the fourth film is conformally formed in the hole.

9. The method for manufacturing a semiconductor device according to claim 1, wherein the first atoms contain n-type impurity atoms or p-type impurity atoms.

10. The method for manufacturing a semiconductor device according to claim 1, wherein the third film is configured to prevent the first atoms in the fourth film from diffusing into the semiconductor layer through the third film.

11. The method for manufacturing a semiconductor device according to claim 1, wherein the first atoms in the fourth film are diffused into the semiconductor layer by a heat treatment.

12. The method for manufacturing a semiconductor device according to claim 11, wherein the heat treatment is performed by heating the fourth film at a temperature equal to or higher than 850° C.

13. The method for manufacturing a semiconductor device according to claim 1, wherein the third film and the fourth film are removed after the first atoms are diffused into the semiconductor layer.

14. The method for manufacturing a semiconductor device according to claim 1, wherein the semiconductor layer is formed in the hole over a charge storage layer.

15. The method for manufacturing a semiconductor device according to claim 1, wherein after diffusing the first atoms into the semiconductor layer, the semiconductor layer includes a first part in the first region and a second part in the second region, the first part contains the first atoms at a first concentration, and the second part contains the first atoms at a second concentration lower than the first concentration.

16. The method for manufacturing a semiconductor device according to claim 15, wherein the semiconductor layer includes a third part in a vicinity of an outer circumferential side surface of the semiconductor layer on a side of the first part, and the third part contains the first atoms at a third concentration lower than the first concentration.

17. The method for manufacturing a semiconductor device according to claim 15, wherein the first concentration is equal to or higher than 1.0×10²⁰ atoms/cm³, and the second concentration is equal to or lower than 1.0×10¹⁷ atoms/cm³.

18. A semiconductor device comprising:
a first film including a first electrode layer and a plurality of second electrode layers that are separated from each other above the first electrode layer;
a charge storage layer provided on a side surface of the first film; and
a semiconductor layer provided on a side surface of the charge storage layer and containing a plurality of first atoms;
wherein the semiconductor layer includes:
a first part containing the first atoms at a first concentration,
a second part positioned above the first part and containing the first atoms at a second concentration lower than the first concentration, and
a third part positioned in a vicinity of an outer circumferential side surface of the semiconductor layer on a side of the first part and containing the first atoms at a third concentration lower than the first concentration.

19. The semiconductor device according to claim 18, wherein the first concentration is equal to or higher than 1.0×10²⁰ atoms/cm³, and the second concentration is equal to or lower than 1.0×10¹⁷ atoms/cm³.

20. The semiconductor device according to claim 18, wherein the third part is in contact with the first electrode layer.
